(19) United States
(12) Patent Application Publication
(10) Pub. No.: US 2024/0241998 A1
(43) Pub. Date: Jul. 18, 2024

(54) STRUCTURE DESIGN SYSTEM AND METHOD

(71) Applicant: Molly STORRS, Bainbridge Island, WA (US)

(72) Inventor: Molly STORRS, Bainbridge Island, WA (US)

(21) Appl. No.: 18/097,066

(22) Filed: Jan. 13, 2023

(51) Int. Cl. G06F 30/13

(52) U.S. Cl. CPC G06F 30/13

(57) ABSTRACT

According to additional aspects of the disclosed subject matter, systems and methods for designing a structure are presented. These include providing a library of predetermined design objects that represent physical and permanent features that may be added and included one or more times within a desired structure. The design objects that collectively form the desired structure (at least at its current design state) may be displayed in a rounded-edge form that encourages early modifications of the desired structure. Advantageously, design objects may be readily moved, as a whole, within a workspace and modifications can be made to design objects without destroying the integrity and completeness of a design object. Additionally, each design object maintains self-referential information that includes position with the workspace, type of design object, dimensions of the object, information regarding structure features or elements of the design object, classifications, target goals for the design object, and the like.

### BACKGROUND

The process of designing a structure, e.g., a building and the elements that go with the building, is a complicated process. The initial design process includes a discussion between an architect and client to generate a plan for a building, designed according to a client's goals. From this meeting (or set of meetings), the architect must translate the information that the client provided into a set of one or more design documents that can be used to further a construction phase.

The initial design process will include the architect laying out a structure according to the design goals. This includes repeatedly placing walls within a “workspace” (where the architect creates the design) which, collectively form rooms, halls, open space, and the like. During this early process, the current tools for moving a room from one location to another currently require deleting one or more walls and redrawing them in another location.

While design changes happen for nearly every design for every architect, the fact is that design changes are least disruptive when they occur during the early stages of design, i.e., when little time has been spent in sketching out the entire building arrangement. Unfortunately, many design changes occur after a structures design has significantly matured. With matured drawings, such late-stage change cause ripple effects throughout the entire design and the architect must return to the “drawing board” to accommodate and update the plans.

It's been observed that one of the features in building design that makes clients, at least early in the process, reluctant to make changes is that building designs are presented in a rigid, engineering-like format, e.g., with squared lines, structure elements displayed, and the like. Due to the official looking nature of the plans in the engineering-like format, a client is often, at least initially, reluctant to change seemingly “fixed” designs—especially initially. When updates finally occur, and there are typically several iterations of design changes, a significant amount of an architect's time is expended to update the plan.

### SUMMARY

The following Summary is provided to introduce a selection of concepts in a simplified form that are further described below in the Detailed Description. The Summary is not intended to identify key features or essential features of the claimed subject matter, nor is it intended to be used to limit the scope of the claimed subject matter.

According to aspects of the disclosed subject matter, systems and methods for designing a structure are presented. These include providing a library of predetermined design objects that represent physical and permanent features that may be added and included one or more times within a desired structure. The design objects that collectively form the desired structure (at least at its current design state) may be displayed in a rounded-edge form that encourages early modifications of the desired structure. Advantageously, design objects may be readily moved, as a whole, within a workspace (corresponding to the desired structure) and modifications can be made to design objects without destroying the integrity and completeness of a design object. Additionally, each design object maintains self-reflective information that includes position with the workspace, type of design object, dimensions of the object, information regarding structure features of the design object, classifications, target goals for the design object, and the like.

According to additional aspects of the disclosed subject matter, method for designing a desired structure is presented. The method device includes presenting a view of a workspace on the display into which design objects may be placed, wherein the workspace represents physical space having defined dimensions within a coordinate system. A set of design objects, wherein each design object of the set of design objects is user-manipulable, has at least two display representations including a rounded-edge type, and maintains self-reflective information of the design object. A first user input is received causing the method to add at least two design objects to the workspace and displaying the workspace with the at least two design objects on a display of the computer system. A second user input is received causing the method to modify the relative location or dimension of a first design object of the at least two design objects. In response to the second user input, modifying the relative location or dimensions of the first design object according to the modified relative location or dimensions of the first design object. A third user input is received, causing the method to export the workspace to one or more design documents.

According to further aspects of the disclosed subject matter, a computer system for designing a desired structure is presented. The computer system comprises a processor and a memory, where the processor executes computer-executable instructions to carry out a design process of a desired structure. The computer system further includes logic, either embodied as software, hardware, or both to present a view of a workspace on the display into which design objects may be placed, wherein the workspace represents physical space having defined dimensions within a coordinate system. The logic further provides a set of predetermined design objects, wherein each design object of the set of design objects is user-manipulable, has at least two display representations including a rounded-edge type, and maintains self-reflective information of the design object. A first user input is received by the logic, causing the computer system to add at least two design objects to the workspace and displaying the workspace with the at least two design objects on a display of the computer system. A second user input is received by the logic, causing the computer system to modify the relative location or dimension of a first design object of the at least two design objects. In response to the second user input, the logic causes a modification to the relative location or dimensions of the first design object according to the modified relative location or dimensions of the first design object. A third user input is received by the logic, causing the method to export the workspace to one or more export documents.

### BRIEF DESCRIPTION OF THE DRAWINGS

The foregoing aspects and many of the attendant advantages of the disclosed subject matter will become more readily appreciated as they are better understood by reference to the following description when taken in conjunction with the following drawings, wherein:

FIGS. 1A-1F are pictorial diagrams of an exemplary computer-generated view showing elements of a computer-implemented system configure to provide rapid design implementation, the diagrams illustrating various progressions during a design phase, all in accordance with aspects of the disclosed subject matter;

FIGS. 2A-2H are pictorial diagrams illustrating the movement and dimension change of design objects within a workspace in accordance with aspects of the disclosed subject matter;

FIG. 3 illustrates a pictorial diagram of a structure design object view of a one-level, existing structure, embodied in a newly configured structure design object, in accordance with aspects of the disclosed subject matter;

FIG. 4 is a pictorial diagram illustrating an exemplary hierarchy of design objects corresponding to the design of a structure, in accordance with aspects of the disclosed subject matter;

FIGS. 5A and 5B are pictorial diagrams illustrating various views of a design objects in conjunction with target goals, according to aspects of the disclosed subject matter;

FIG. 6 is a block diagram illustrating an exemplary computer-implemented routine for updating self-reflective information of a design object in response to a movement of the design object, in accordance with aspects of the disclosed subject matter;

FIG. 7 is a block diagram illustrating an exemplary computer-implemented routine for updating self-reflective information of a design object in response to a resize of the design object, in accordance with aspects of the disclosed subject matter;

FIG. 8 is a block diagram illustrating an exemplary computer-implemented routine for conducting a structure design in accordance with aspects of the disclosed subject matter;

FIG. 9 illustrates exemplary tables as may be generated in an export of a workspace, in accordance with aspects of the disclosed subject matter;

FIG. 10 is a block diagram illustrating an exemplary computer-readable medium encoded with computer-executable instructions to carry out a routine for efficient structure design in accordance with aspects of the disclosed subject matter; and

FIG. 11 is a block diagram illustrating an exemplary computing system configured to enable easy, robust and rapid design of structures according to various aspects of the disclosed subject matter.

### DETAILED DESCRIPTION

According to aspects of the disclosed subject matter, systems and methods for designing a structure are presented. These include providing a library of predetermined design objects that represent physical and permanent features that may be added and included one or more times within a desired structure. The design objects that collectively form the desired structure (at least at its current design state) may be displayed in a rounded-edge form that encourages early modifications of the desired structure. Advantageously, design objects may be readily moved, as a whole, within a workspace (corresponding to the desired structure), and modifications can be made to design objects without destroying the integrity and completeness of a design object. Additionally, each design object maintains self-reflective information that includes position within the workspace, type of design object, dimensions of the object, information regarding structure features of the design object, classifications, target goals for the design object, and the like.

For purposes of clarity and definition, the term “exemplary,” as used in this document, should be interpreted as serving as an illustration or example of something, and it should not be interpreted as an ideal or a leading illustration of that thing. Stylistically, when a word or term is followed by “(s)”, the meaning should be interpreted as indicating the singular or the plural form of the word or term, depending on whether there is one instance of the term/item or whether there are multiple instances of the term/item. For example, the term “user(s)” should be interpreted as one or more users.

For purposes of clarity and definition, the term “self-reflective” corresponds to the ability of a design object to provide information regarding various aspects of the design object, including but not limited to its dimensions or size, its position within the workspace/project, classifications of the design object, specific limitations to the design object, minimum and/or maximus sizes or dimensions, and the like.

The terms “structure features” and “structure elements” should be viewed as synonymous and refer to elements or items that occupy space and have dimensions. Typically, though not exclusively, these structure features are viewed (at least during the design process) integral features to another structure. For example and by way of illustration, an office will typically have 4 walls, and while many people (including clients) do not think about the walls as structure elements, each wall is typically 4 or 6 inches thick (though cubicles often have a 2 inch wall/structure element). In short, walls (and other features) take up space within a building. However, the space walls occupy is typically not “usable” space—space that can be used by one that occupies the office. The usable space plus the structure space is referred to herein as the gross space (sometimes expressed as gross area) of a given design object and the usable space is referred to herein as the net space of that design object. According to embodiments of the disclosed subject matter, while design objects track both their gross space and useable space and while design objects may be configured to report information in gross space, as a default the design objects report their “space” in terms of useable space. Reporting in usable space coincides with the preferences of most clients who are typically concerned with the amount of usable space for a given office, conference room, cubicle, atrium, etc.

Regarding the library of predetermined design objects (also referred to as the “design object library” or, in many cases, just the “library”), in accordance with aspects of the disclosed subject matter, the design object library comprises a plurality of predetermined design objects of various shapes, sizes/dimensions, purposes, classifications and the like, which may be included in a workspace. Indeed, the design object library will typically include a design object for a structure/building, open spaces, and other physical features that may be added to a workspace. The design object library may also comprise sub-libraries (and nested sub-libraries). In many instances, though not exclusively, sub-libraries may be grouped together according to a purpose. For example and by way of illustration and not limitation, a sub-library may correspond to design objects that are particularly suited and configured for designing a hospital, or a school, or a residence. Design objects may be user-configured added to the design object library. In some instances, a user may wish to configure and add a design object corresponding to an existing structure, where the design object includes the existing structure's perimeter as well as additional objects (such as stairwells, elevators, utility rooms, etc.) that still and/or must remain within the building, while representing the remained as blank and available for a redesign. Each design object is suitably configured to provide all or some of its self-reflective information when queried.

According to aspects of the disclosed subject matter, design objects in the design object library are user-modifiable. Some design objects in the library may have limits upon the modifications that may be made. For example, elevator design objects may have a fixed size that cannot be modified, but classifications to the elevator design objects may be made. In many, perhaps most, instances design objects may be user-modified according to and without limitation: location within a workspace, size, shape, orientation (within a workspace), level, classification, structure features, design object type, and the like. Design objects are associated with dimensions and each design object is self-reflective in that each object maintains self-reflective information regarding its place (location, size, orientation, shape and classification) within a workspace (which may include default values), target information for a particular workspace, rendering information (e.g., hard-edge or rounded edge, with or without dimensional information or type displayed), and formulae or routines for calculating its space (both gross and net space), and these are used, as needed, when an object is modified.

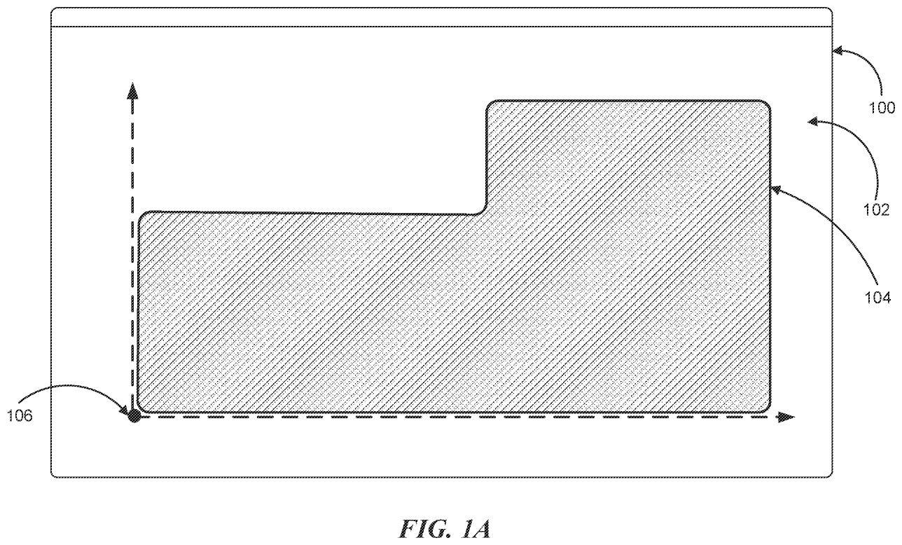

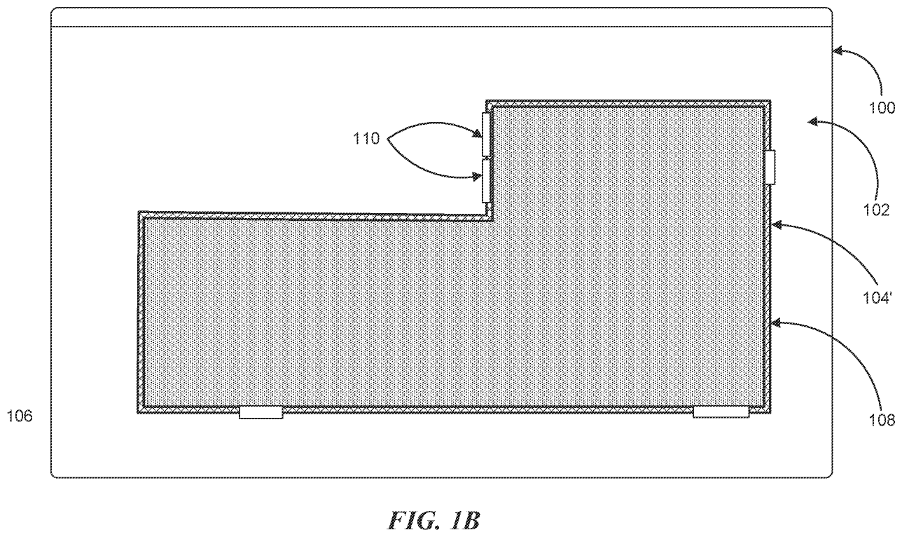

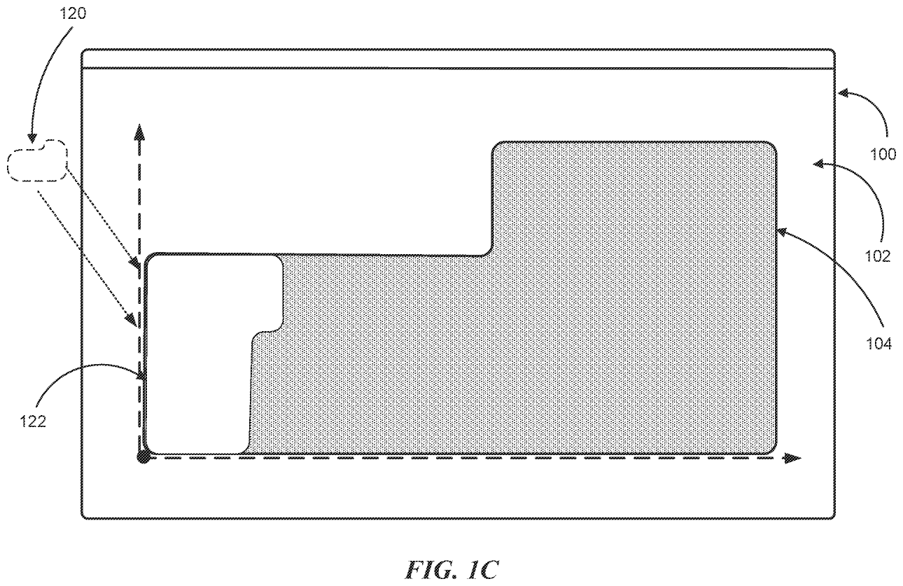

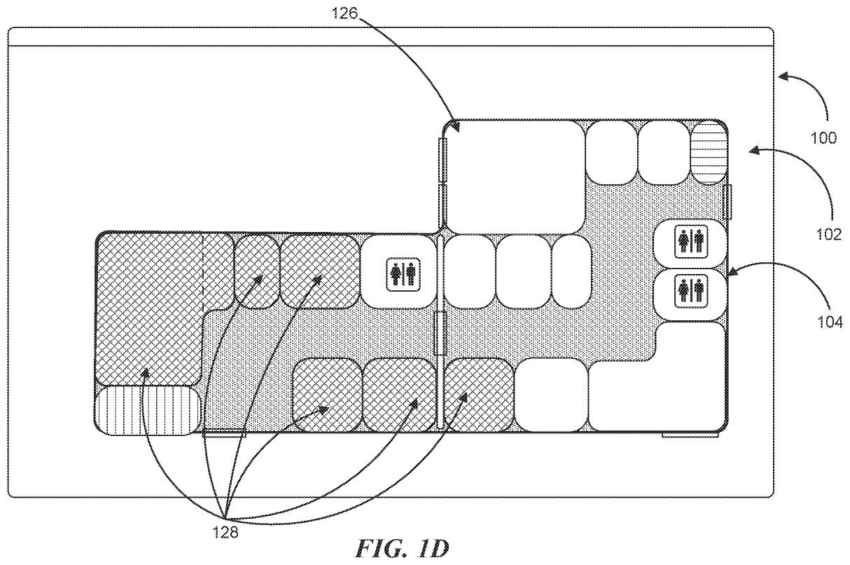

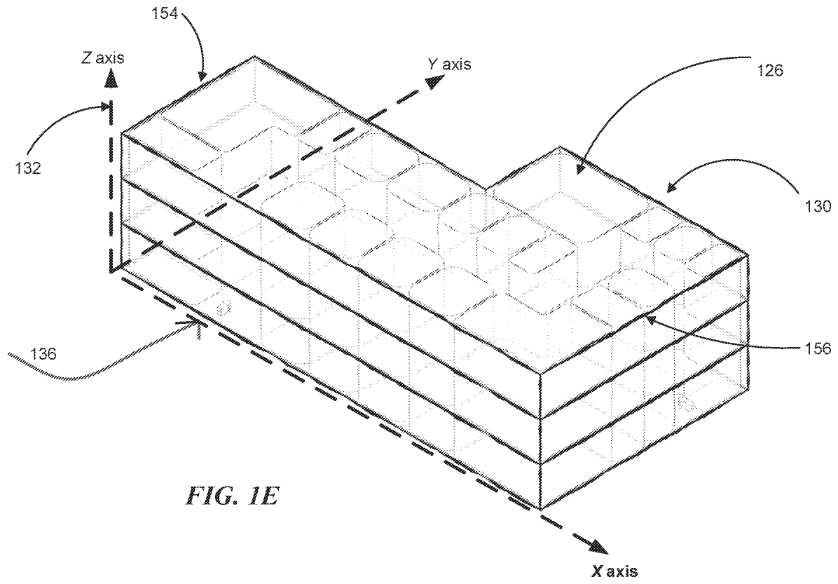

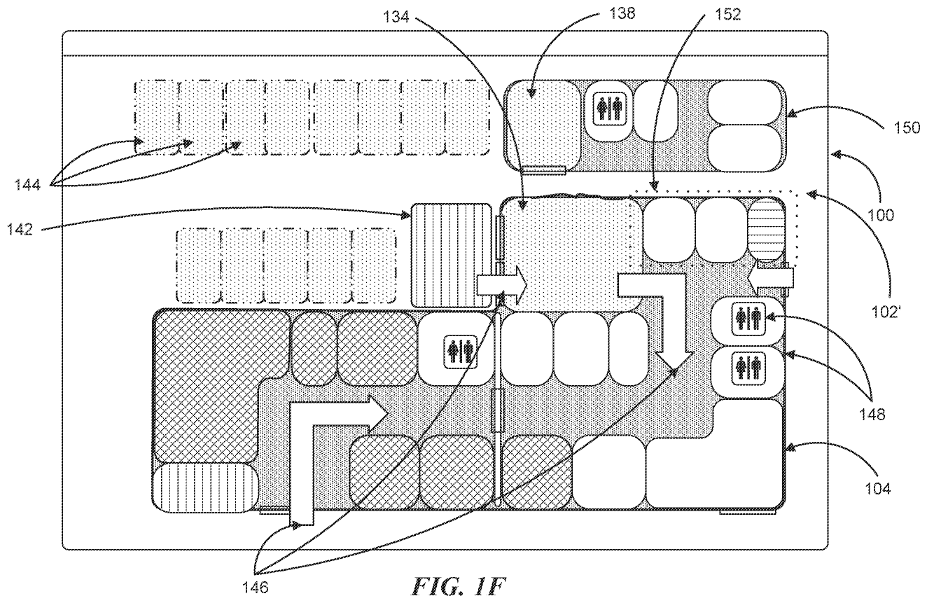

Turning to FIGS. 1A-1F, these figures illustrate pictorial diagrams of an exemplary computer-generated view 100 showing elements of a computer-implemented system configure to provide rapid design implementation through various progressions during a design phase, in accordance with aspects of the disclosed subject matter. The computer-generated view shows a workspace view 102 in which a design for a structure may be developed and modified using one or more predetermined design objects from a library of predetermined design objects, all in accordance with aspects of the disclosed subject matter.

Regarding the design of a structure and using one or more input devices associated with the computer-implemented system, a user (e.g., an architect) may quickly create and modify the overall arrangement and dimensions of a structure utilizing various computer-implemented tools and controls including, but not limited to, the library of predefined design objects, mouse movements, menus, and the like. As a beginning step of creating and establishing an overall arrangement of a desired structure, as well as surrounding features, information regarding size and contours of a particular area or location, surrounding features, and the like may be provided to the computer-implemented system through the various user input devices. As part of the system to design the desired structure, when objects are added to the workspace, the workspace view 102 may be generated to reflect the workspace's current state. By way of illustration and example, workspace view 102 includes a structure design object view 104 which is rendered/displayed in the scale of the workspace view.

With respect to the display of the various objects within the workspace, each design object may be displayed or presented in the workspace view 102 in one of at least two forms: a rounded-edge form and a hard-edge form. As shown in the workspace view 102 of FIG. 1A, the structure design object added to the workspace, as represented by structure design object view 104 in workspace view 102, is displayed using a rounded-edge form, i.e., the edges of walls or boundaries are rounded and structure elements (e.g., walls shown in dimension (thickness), doors, windows, etc.) are not displayed. In contrast to rounded-edge display, design objects displayed in a hard-edge form display edges of design objects as they are intended, and frequently, though not exclusively, include structure elements. FIG. 1B illustrates the hard-edge form display of structure design object 104′ which includes display of structure elements including walls 108 and doors 110.

Advantageously, design objects that are presented or displayed in rounded-edge form, appear as more informal and less rigid, more easily adapted and changed. This leads to early modifications by the client and reduces the number of design change iterations that typically occur.

In accordance with aspects of the disclosed subject matter, each design object, including the structure design object of each workspace or project, is associated with self-reflective information. This self-reflective information includes dimensions of the desired structure, information corresponding to a display scale, a set of classifications, target sizes, etc. Other information, such as counts, building level and the like may also be included in the self-reflective information. With the structure design object as the top-most design object associated with workspace, a cartesian coordinate system is established from which the location for all other design objects in the workspace is determined, determined either directly or indirectly via intervening design objects. For example and by way of illustration, origin 106 may be established as a coordinate of {0, 0, 0} in a cartesian coordinate system for the workspace. Dimensions for the structure design object, as well as other design object in the workspace, may be identified according to the measure used for the structure design object, e.g., metric or Imperial measurements.

With the structure design object added to the workspace, additional design objects can be added, including design objects within and without the structure design object. Design objects that may be added to the structure design object, as illustrated as structure design object view 104, may include, by way of illustration and not limitation, offices, restrooms, open space, conference rooms, utility closets, loading bays, permanent fixtures (e.g., counters, kiosks, fountains, planters) stairwells, elevator shafts, sky bridges, and the like. In accordance with aspects of the disclosed subject matter, each of these design objects is part of a library of predefined design objects from which a user can select, add to, orient, position, and size within the workspace. By way of illustration and turning to FIG. 1C, this figure shows a rounded-edge display of a conference room design object with an attached closet, as represented by design object view 122. In this figure, the conference room design object is added to the workspace within the structure design object. Illustratively, a user, via an input device of the computer system, selected a predetermined conference room design object 120 from the library of predetermined design objects, and added, positioned and oriented the conference room design object within the workspace. In this example and according to aspects of the disclosed subject matter, the conference room design object may obtain its coordinates within the workspace and its dimensions from the structure design object or, alternatively from the workspace.

In accordance with additional aspects of the disclosed subject matter, multiple design objects may be organized into a set, with the design objects within the set having specific sizes, orientations, relative positions, and/or classifications, and included in the library as a type of design object. When a user selects a set from the library, the design objects of the set are included in the workspace having the established relationships of the set. This is particularly useful when certain types of design objects regularly co-occur as well as being useful for ensuring alignment between levels. An example of a set of design objects may include elevators shafts and a stairwell, as shown by block 152 of FIG. 1F.

In various non-limiting embodiments of the disclosed subject matter, the library of predefined design objects may be accessed in response to user input via activation of a menu (e.g., a drop-down menu) that shows all predefined design objects directly, in a scrollable view, and/or as a series of sub-menus, as well as an option to create/define another design object from which the user can select. As part of adding a new predefined design object to the workspace, the dimensions of the added design object, as well as coordinates of added design object are established and included in the self-reflective information of the design object. Indeed, according to aspects of the disclosed subject matter, a user may define an object of arbitrary shape and size including, by way of illustration and not limitation: polygons, shapes with curved edges, shapes with straight and curved edges, shapes with edges that cannot be resized or reshaped, shapes having specific structure elements, and the like. Default classifications may be established for any newly defined design objects, as well as minimum and/or maximum sizes (which may include minimum and/or maximum heights for the design object). Default presentation information (solid or dashed lines, colors, pattern fill, etc.) may be included with any newly added design object. Additionally, information for determining the gross and usable space of a newly added design object may be automatically determined or provided by the user adding the design object.

Sizing or resizing the design object, once added to the workspace, causes the dimensions (relative to the cartesian coordinate system of the structure design object) to be updated in the self-reflective information of that design object. Orienting (i.e., rotating and/or flipping) the design object in the workspace similarly may cause updates to the dimensions and location of the design object, and updated information as to the dimensions and/or location is updated as part of the object's self-reflective information. Classifications, discussed below, may be assigned to a newly added design object and these classifications are also maintained in the self-reflective information for the corresponding design object.

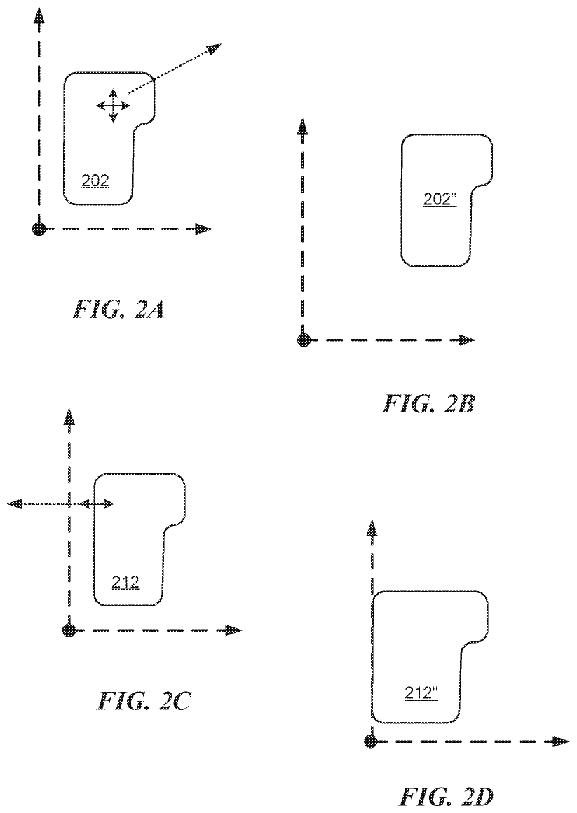

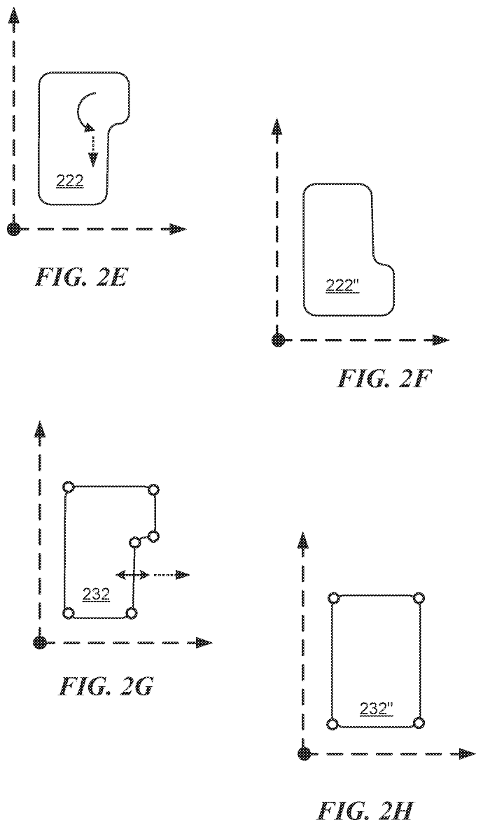

As suggested above and according to aspects of the disclosed subject matter, design objects may be moved and/or sized by a user. To illustrate, reference is made to FIGS. 2A-2H. FIGS. 2A-2H are pictorial diagrams illustrating movement and dimension change of design objects within a workspace, in accordance with aspects of the disclosed subject matter. More particularly and with reference to FIGS. 2A and 2B, these figures illustrate how a user might easily move a design object 202 within a workspace. By way of example, assume that design object 202 is located at cartesian coordinate {1,1,0}. In one example and as shown in FIG. 2A, a user may place a cursor within the lines of the design object and perform a drag operation, thereby moving the design object as a whole to a new location in the cartesian coordinate system, as shown in FIG. 2B by design object 202″, now located at coordinates {4,3,0}. As part of the movement of the design object, the coordinates of the design object relative to the cartesian coordinate system are updated in the self-reflective information of the design object. Advantageously, the ability to move design objects, as a whole instead of separately relocating/moving all walls of a space, represents a significant advance in structure design.

In addition to moving design objects as a whole and according to additional aspects of the disclosed subject matter, a user (via one or more input controls) is also able to resize a design object without breaking the design object, e.g., resulting in an unenclosed office as a wall is moved, and updating the dimensions and (potentially) the coordinates of the design object in the self-reflective information of the object. As shown in FIG. 2C, a user can move an edge of a design object 212, using a drag operation with a mouse originating on a wall. The results of dragging an edge of a design object are shown in FIG. 2D as design object 212″. In this instance, the coordinate location of the design object (from 212 to 212″) changed, as well the dimensions and overall area or space of the design object were updated, and this updated information is kept as part of the self-reflective information of the object.

Another modification to a design object includes reorienting (rotating) or “flipping” a design object (horizontally and/or vertically). By way of illustration and not limitation, FIG. 2E illustrates an exemplary user interaction showing a flipping used in conjunction with a mouse clip and drag operation to vertically flip design object 222, resulting in the arrangement of design object 222″ as shown in FIG. 2F. Of course, flipping, while maintaining the volume or area of the design object, may cause the original (location reference point of the design object) to change, and thus this modification may result in the self-reflective information being updated.

Yet another user modification to a design object includes reshaping a design object. Indeed, while it is entirely practical to delete a design object that is not the right shape and replace the deleted design object with another, appropriately shaped design object, in various embodiments of the disclose subject matter, the shape of a design object may be modified. According to aspects of the disclosed subject matter, FIG. 2G illustrates a portion of a user interaction with regard to display object 232 such that defining points of the shape of the design object are presented, thereby allowing a user to select an edge of the shape and move it perpendicularly one way or another. For illustration and not limitation, and as shown in FIG. 2H, the action of moving one edge of the design object 232″ is shown. Of course, reshaping a design object will likely change the volume or useable area of the design object, as is the case in the change from design object 232 to design object 232″, such that the self-reflective information for the design object must be updated upon a reshape modification. Similarly, it may be that the origin or location reference point of the reshaped design object is changed which would mandate an update of its location in the self-reflective information. Regarding reshaping, while there may be times that a substitution of one design object for another would be most simple, an advantage of reshaping a design object is its retention of classification information, e.g., to which business group is a reshaped design object allocated.

Other modifications to a design object include modifications to the classifications, e.g., type of design object, allocated group, minimum and/or maximum sizes, and the like. Advantageously, irrespective of any modifications to a design object, the integrity of the design object, as a unit or whole, is not disrupted. In other words, moving, flipping, reorienting, reshaping, resizing and/or reclassifying may change some aspect of the design object, but does so without destroying the structure and maintains or updates all self-reflective items of information.

Turning back to FIG. 1D, this figure shows the results of various iterations of adding design objects, sizing, orienting, and placing the design objects within the workspace, as shown in workspace view 102. Corresponding updates from the locations, dimensions, classifications, and target goals to each design object's self-reflective information are maintains for each design object.

It should be noted that while the desired structure view 104 in FIG. 1D shows a single level, the present invention is not so limited. Indeed, according to aspects of the disclosed subject matter a workspace/project may include multiple levels, each represented as a design object. Additional design objects may be added to a specific level. Input controls may be used to display individual levels which would enable a user to design the desired structure. Alternatively, multiple levels may be displayed in the workspace view 102 and use display techniques such as transparency and pivoting the display of the structure view 104 may enable or facilitate such editing. Further, in addition to rounded-edge and hard-edge display forms, the views of the workspace may be displayed in a rotated and/or pivoted manner, with or without transparency of each design object.

Regarding the pivoting and/or rotation, in accordance with additional aspects of the disclosed subject matter and as indicated above, a workspace may be displayed in both a 2-D (two dimensional) or 3-D (three dimensional) manner. Indeed, while FIGS. 1A-1D illustrate a 2-D display of the corresponding workspace 104, in an alternative embodiment the computer system may be configurable such that a workspace is displayed in a 3-D manner. Of course, it will be readily appreciated that when the workspace is displayed in a 3-D manner, that display “tilted” or “pivoted”, i.e., an oblique angle associated with the z-axis relative to the display view. Indeed, without pivoting or rotating the display such that the z-axis does not point directly at the user, the workspace display would result in an effective 2-D display. Further, in addition to the z-axis being titled at an oblique angle to the user/viewer, the various design objects in the workspace may be displayed with a measure of transparency, e.g., 70% transparent/30% opaque (though any percentage of transparency, between 0 and 100, may be selected). Advantageously, utilizing transparency in conjunction with a 3-D presentation of the workspace enables simultaneous and aligned display of multiple levels of design objects that have been included within a workspace.

Turning to FIG. 1E, this figure illustrates a 3-D workspace view 130 of a workspace with the z-axis 132 being directed to an oblique angle relative to the user/viewer, and further illustrates the use of transparency in display object views and their simultaneous and alignment in the workspace, all in accordance with aspects of the disclosed subject matter. Illustratively and by way of example, the workspace is now shown as having three levels/floors and the various design objects included in the workspace are displayed in rounded-edge form and with transparency. Indeed, this figure further illustrates how the foyer design object, represented as foyer view 126 of FIG. 1D, extends up through each level. Similarly, the stairwells shown in FIG. 1D are also extended through each of the levels shown in the workspace view 130.

In addition to adding design objects within the perimeter of a structure design object, and in accordance with aspects of the disclosed subject matter, design objects may be added to the workspace that fall outside of the perimeter of a structure design object. Indeed, in embodiments of the disclosed subject matter, multiple structure design objects (e.g., each representing a distinct building) may be added to a workspace. Permanent features that are not necessarily “structure” may also be added to a workspace. Indeed, turning to FIG. 1F, this figure illustrates the workspace view 102′ that includes views 104 and 120 of multiple structural design objects, an entry stairs view 122 of an entry design object, as well as parking views 124 of parking design objects for the buildings, all included in the workspace.

According to aspects of the disclosed subject matter, and as shown in FIG. 1F, various annotations may be added to a workspace. By way of illustration and not limitation, flow arrows, such as flow arrows 126 illustrated in the workspace view 104, may be added to visually demonstrate how people might move around within the designed workspace. Labels and/or icons, such as icon 128, may be added to design objects and/or the workspace to provide visual clues as to the nature of a given design object. According to various aspects of the disclosed subject matter, design objects may be configured to display apparent user-drawn lines to suggest informality of the current stage or phase in designing a desired structure. The includes of these apparent user-drawn lines creates a sense of informality in the current state of the workspace which, in turns, engenders a sense in the client that it is entirely acceptable to modify the design. By way of example, foyer view 130 of a foyer design object includes both apparent user-drawn lines and a pattern that suggests that the design object represents an open space.

With reference to FIG. 1E, hand-drawn line 136 indicates flow for entering the designed structure 130. According to aspects of the disclosed subject matter, this type of annotation to a designed structure may be used with respect to 3D representations. Also, FIG. 1E illustrates the combined use of hard-edge representation (for the building structure) and rounded-edge representations (for the internal design objects). Further, FIG. 1E illustrates the use of apparent user-sketched lines, e.g., lines 154 and 156, to give a sense of informality to the design and encourage early design updates.

According to aspects of the disclosed subject matter, as suggested above, a user may add to the library of predetermined design objects. This is especially important in the case that an existing structure is to be used, where the designing of the structure is the arrangement of objects within or added onto the existing structure. As embodiments of the disclosed subject matter, a user may create and configure a design object, as a structure design object, to mirror the existing structure and permanent features that exist within the existing structure. Advantageously, a newly added structure design object may include multiple levels (and/or automatically trigger that a corresponding number of levels be added to the workspace) to reflect the existing, permanent fixtures and features of the existing structure. By way of illustration and not limitation, open area 134 is shown in a dotted pattern fill to indicate that this is an open area. Similarly, open area 138 includes a similar dotted pattern fill to indicate open space.

In accordance with additional aspects of the disclosed subject matter, predetermined design objects in the library do not need to be fully enclosed spaces. For example, a cubicle or carrel may have only 3 walled (partitions) sides. Additionally, in various embodiments, a design object may correspond to an open space, such as a seating or lounge area, a foyer, and the like. Display of design objects corresponding to open space may include, by way of illustration and not limitation, any one or more of outlining the display view with a dashed line, filling the display view with a particular pattern or color, and the like. By way of illustration, parking spaces 144 are illustrated with dashed lines indicating their open space and lack of physical structure.

Additionally, while most of the design objects presented in the figures have straight walls (or space) that defines the perimeter of the design object, the present invention is not so limited. Indeed, predetermined design objects may correspond to space whose perimeter is entirely rounded or curved. For example and by way of illustration and not limitation, a round- or elliptical-shaped kiosk or a circular staircase may be included among the predetermined design objects available for use in a workspace.

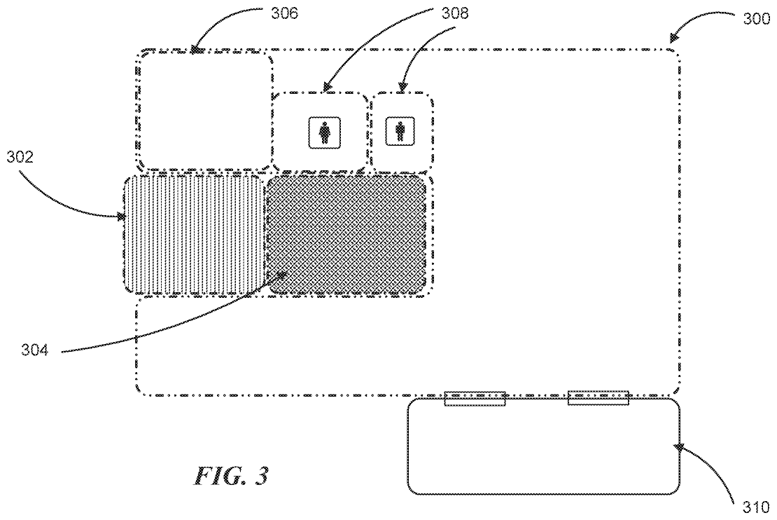

Turning to FIG. 3, this figure illustrates a pictorial diagram of a structure design object view 300 of a one-level, existing structure, embodied in a newly configured structure design object, in accordance with aspects of the disclosed subject matter. Illustratively, the existing structure design object includes various existing interior physical features (as design objects in a workspace) such as and as represented by entry stairs view 302, entry parquet view 304, exhibit room view 306, and restroom views 308. Correspondingly, the existing structure design object and other design objects corresponding to the existing physical features, are specifically marked as non-manipulable, including not moveable, not re-orientable, nor resizable, and not delectable. Additionally, some classifications, though not necessarily all classifications, may be non-manipulable. According to aspects of the disclosed subject matter, when a structure design object is non-manipulable, exterior additions may to the existing structure may be represented by locating “addition” design objects proximate to the existing structure, as represented in FIG. 3 as addition design object view 310. Additionally, existing feature design objects may be displayed in a manner, such with dashed lines as illustrative used in the structure design object view 300 of FIG. 3, to indicate that the corresponding design objects are non-manipulable.

As mentioned above and according to aspects of the disclosed subject matter, each of the design objects used in designing a structure may be classified with one or more classifications. Some of these classifications may be predefined, common classifications including, by way of illustration and not limitation: object type such as office, restroom, closet, utility room, door, stairwell, conference room, and the like; grouping such as engineering, research, business group, and the like; and feature such as fountain, planter, kiosk, etc. Some classifications, if present/set for a design object, may correspond to restraints that affect if or how the design object can be modified. For example, restrooms in public facilities must meet government-mandated minimum sizes which prohibit sizing the corresponding object below those minimums.

In implementation and according to aspects of the disclosed subject matter, some of the classifications may be maintained as a set of Boolean values or flags (like bits in a word of memory) such that if the flag is set, then the design object has that feature/classification. For example, if a flag corresponding to “office” is set, the design object is an office. In some instances, classifications may need corresponding values and would, therefore, be maintained as a set of tuples: the classification and corresponding values. Similarly, classifications may be represented by one of several enumerated values. By way of example, a design object corresponding to a restroom, having minimum sizes, may be stored as a tuple.

Typically, though not exclusively, a design object may be assigned with multiple classifications. For example and with reference back to FIG. 1D, a design object, such as design object 122, may be classified as an office and may be classified as belonging to a particular grouping or enumeration, such as “Engineering.” According to aspects of the disclosed subject matter, the display or presentation of a design object in the workspace view 102 may be determined according to the classifications of the design object. Indeed, the classifications of a display object may affect how the display object is presented, including a color or colors, patterns, symbols (handicapped, restroom, stairwell, etc.), and/or transparency/opacity. A design object having a grouping classification corresponding to “Research” may be displayed with a particular color or pattern, such as shown as items 128 in the workspace view 102 corresponding to a conference room display object as well as multiple office design objects. In many instances, multiple classifications may be depicted utilizing multiple display features: e.g., foreground color, background color fill pattern, hashing pattern, and the like. Design object view 104 of FIG. 1A illustrates the use of fill and hashing to indicate multiple classifications, e.g., engineering and staff only.

While management of design objects may be implemented in a variety of manners, including a set of design objects added to a workspace, another alternative is to maintain and manage design objects of a workspace as a hierarchy of design objects. In a hierarchy a workspace would have an initial structure design object corresponding to the overall structure, such as the structure design object discussed above and represented as the structure design object view 104 in FIG. 1A. Under a hierarchy, additional design objects added to the workspace would be added to a corresponding location in the hierarchy. In this way and according to various embodiments of the disclosed subject matter, design objects could be added within other design objects.

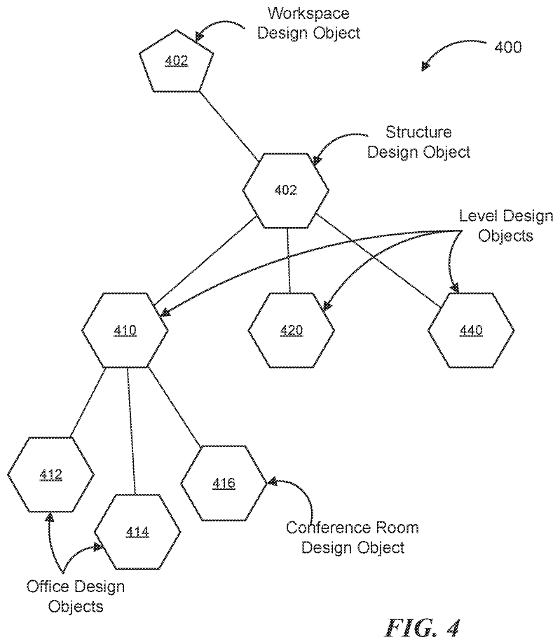

Turning to FIG. 4, this figure illustrates an exemplary hierarchical arrangement 400 for managing design objects in a project/workspace corresponding to a desired structure. In this example, a workspace design object 402 is added or established, and a structure design object 402 is added to the workspace under or within the workspace object. As discussed above, a cartesian coordinate system and a scale of measurement is established for the structure design object. As described above, the structure design object corresponds to the overall design or arrangement of the desired structure, at least until modified. As shown in this example, three level design objects 410, 420 and 430 have been added to the structure design object 404. Each level design object includes design objects added by a user, and that reside on the corresponding level in which they are included in the hierarchy 400, such as design objects 412-416 residing on the level corresponding to level design object 410. By way of illustration, the design objects 412-416 include offices (represented by office design objects 412 and 414) and a conference rooms (represented by conference room design object 416). Position, orientation and dimension information of each design object in the hierarchy may be determined relative to the design object's parent (i.e., another design object to reaches to the workspace design object 402.).

Having an arrangement of hierarchy among design objects readily facilitates each design object being able to identify its location and size by referring to its parent, and with the parent referring to the project. Of course, when maintaining design objects in a set for a workspace, the location and dimensions of design objects can be readily determined as well.

According to aspects of the disclosed subject matter, target goals may be established for a workspace. Target goals may include totals, limitations, requirements and the like. By way of illustration and not limitation, target goals may include a specific number of offices with the workspace, a maximum number of offices, and/or a minimum number of office within the workspace; an aggregate amount of space (often expressed in area) for offices, conference rooms, utility rooms, stairwells, elevators, kitchen areas, and the like; open areas and corresponding sizes; a number of levels; an amount of area to be allocated to a particular classification, e.g., engineering, research, sales, etc.; the number of levels/floors; conditioned not conditioned air; accessibility units, overall space/area; and the like. Target information is often shared among the design objects within a workspace and used to determine totals and averages regarding overall area/size, differences between targets and actual values; counts of various design objects (overall and/or allocated to various classifications) and the like.

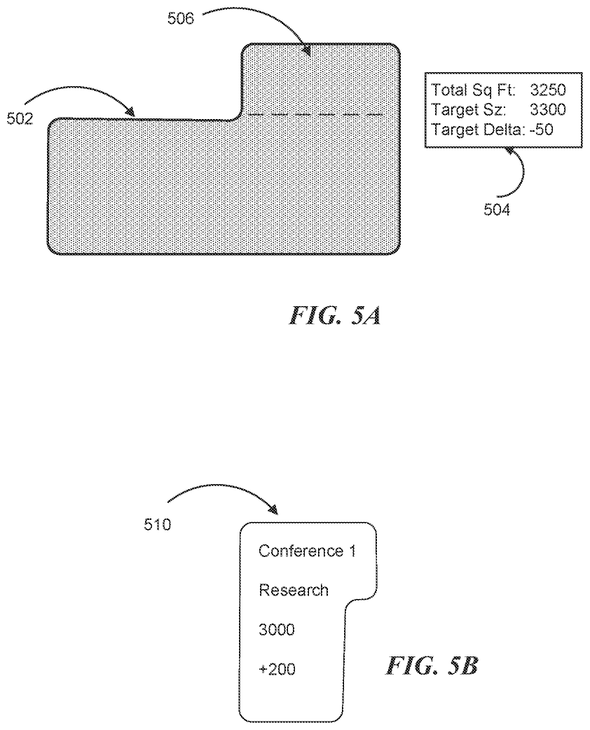

In various embodiments, the target goals may be displayed with respect to an individual design object that has been included in the workspace. Indeed, in some embodiments of the disclosed subject matter, a design object may be displayed in such a manner as to indicate actual size and related target information. For example, turning to FIGS. 5A and 5B, these figures are pictorial diagrams illustrating various views of a design objects in conjunction with target goals, according to aspects of the disclosed subject matter. For example and by way of illustration and not limitation, FIG. 5A, shows a conference room design object view 502 with shading corresponding to a Research classification. Correspondingly, according to the self-reflective information and target goals, information view 504 shows information regarding the total area of the corresponding conference room design object (3250 square feet), the target area of the conference room design object (3300 square feet), and a target delta (−50 square feet) indicating that the conference room design object is 150 square feet smaller than the target goals. In an alternative conference room design object view 510 as shown in FIG. 5B, self-reflective information of the corresponding conference room displayed in the view indicates that this is the first conference (“Conference 1”), at least one classification of the object indicates that it is allocated to a “Research” grouping, that the size of the design object within the structure is 3000 square feet, and that the design object is 200 square feet over a targeted goal.

According to aspects of the disclosed subject matter, the current size information describes the net space of the design object, i.e., usable (or net) space for the corresponding conference room design object. Information such as gross space may be displayed upon appropriate configuration of the design system by a user. Whereas usable or net space corresponds to the space of the design object available to use, the gross space of a design object includes structure features that are not usable. Features such as wall thickness and structure elements are included in the calculation of the gross space of a design object. Some features of a design object may be included or excluded from usable space. For example and with reference to FIG. 5A, an attached closet, as indicated by the object area view 506 of the conference room design object, may or may not be considered in the calculus of usable space. For this example, the area of the attached closet is not included in the shown net space.

Regarding the display of self-reflective information of design objects, information for classifications, singularly and in combination with others, can be displayed as well as contrasted to target goals for the project, e.g., the number of offices allocated to a research classification. Information regarding design objects with the requested classifications, as well as counts of the objects, may be aggregated and presented. For example, information regarding all offices allocated to engineering may be aggregated by identifying the design objects within the project that have the specific set of classifications, accessing the self-reflective information for design objects of the classification(s), aggregating the information, and presenting the aggregated information. Similarly, self-reflective information corresponding to the entire project may also be displayed by aggregating the self-reflective information of all design objects.

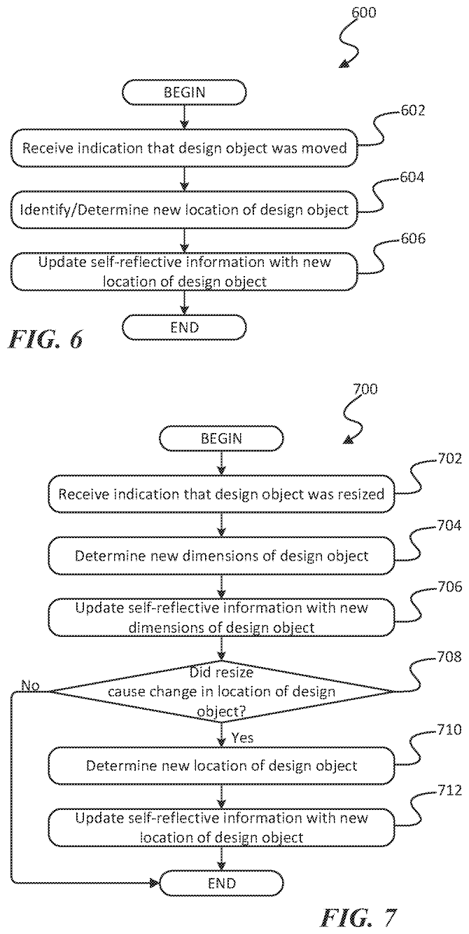

Turning to FIG. 6, this figure is a flow diagram illustrating an exemplary computer-implemented routine 600 for updating the self-reflective information of a design object when moved, according to aspects of the disclosed subject matter. According to this routine, at block 602, information is received indicating that a particular design object has been moved. In various embodiments, changing the orientation of a design object may be viewed as a movement. Regarding the movement and by way of example and without limitation, an inter-process signal may be generated to a monitoring process of the routine 600 by a design object each time the position of the design object is modified.

At block 604, the routine 600 identifies the new location of the moved design object. As suggested above, the new location is based on the cartesian coordinate system of the structure design object. At block 606, the self-reflective information of the design object is updated with its identified location. This updated information, that will typically include an x-value and a y-value (pertaining to the cartesian coordinate system) will be updated in the self-reflective information for the moved design object. Additionally, a z-value may also be included in the updated information, especially in the case where the moved design object was relocated on a different level. Alternatively, when a design object changes a level (or elevation), a classification value corresponding to level may be updated. After updating the new location of the design object, the routine 600 terminates.

FIG. 7 is a flow diagram illustrating an exemplary computer-implemented routine 700 for updating the self-reflective information of a design object when the design object is resized. Upon detecting that a design object has been resized (as discussed above), at block 702, the routine 700 determines the dimensions of the newly sized design object. According to aspects of the disclosed subject matter, the dimensions of the newly sized design object are determined according to the scale of the structure design object. In various embodiments, this scale information may be obtained from a parent design object in a hierarchy, by reference to globally available information regarding the scale (relating display information to metric or imperial measurements), referencing the structure design object, or the like. At block 704, with the dimensions determined, the overall space of the design object is determined and updated in it's the self-reflective. In some instances, resizing a design object may change the design object's location in the cartesian coordinate system. Accordingly, at block 706, a test is made as to whether the design object, through its resizing, has moved in the cartesian coordinate system. If so, at block 708, the resulting location of the newly sized design object is updated in the self-reflective information. At block 708, target information including delta values corresponding to target goals is updated in the self-reflective information. Thereafter, the routine 700 terminates.

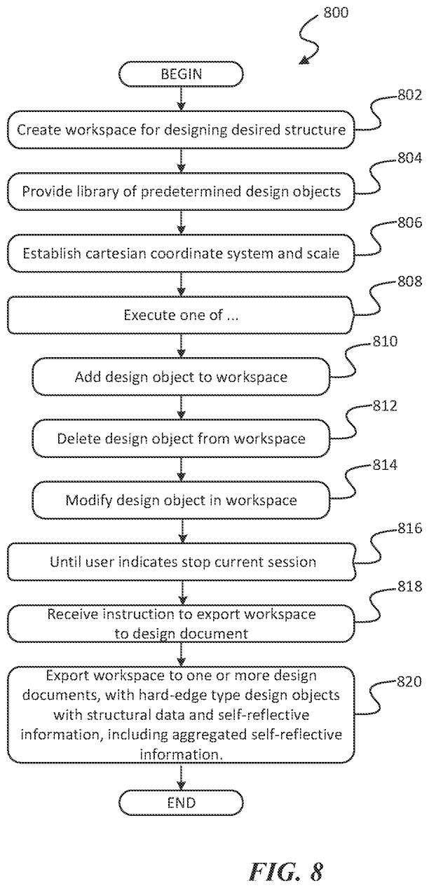

FIG. 8 is a flow diagram illustrating an exemplary computer-implemented routine 800 for designing a desired structure, configured in accordance with aspects of the disclosed subject matter. At block 802 and in response to a user request, a workspace for designing a desired structure is created. As suggested above, creating a workspace may comprise creating or generating an instance of a workspace design object in which the desired structure may be designed. Alternatively to creating a new workspace, at block 802 an existing workspace may be opened.

At block 804, a library of predetermined design objects that may be added to the created workspace is provided. As indicated above, these design objects may include, by way of illustration and not limitation, office design objects, conference room design objects, kiosk design objects, other permanent features of a desired structure.

At block 806, a cartesian coordinate system for the workspace is established, as well as a scale for the workspace. At block 808, a looping structure is begun, where one of alternative steps 810, 812 and 814 is carried out with each iteration, and where at 818 an evaluation is made to continue iteration or move forward in the routine. Thus, if block 810 is to be executed, a design object is added to the workspace according to user instructions. For purposes of block 810 of routine 800, adding a design object includes positioning the design object within the workspace, establishing an orientation of the design object, classifying the design object, sizing the design objects, obtaining target information and the like. Self-reflective information for the added design object is updated and maintained in the object.

If block 812 is to be executed, a design object within the workspace is identified and removed from the workspace. If block 814 is to be executed, a design object identified by a user is modified. Modification may include re-orienting the identified design object within the workspace, resizing the design object, repositioning the design object, adding/removing classifications of the design object, and the like.

At block 816, if the user indicates a stop or an end to the design process session (at least for the time being) the routine 800 proceeds to block 818. Alternatively, the routine 800 returns to block 808 for additional instruction and repeats as set forth above.

At block 818, an instruction to export or generate the workspace as a design document is received. Correspondingly, at block 820, the workspace, which includes all design objects included in the workspace, is output as one or more design documents. According to aspects of the disclosed subject matter a design document includes an early schematic drawing of the workspace, typically rendered in hard-edge form which also typically include structure elements. Additionally, the design document or documents include tables of self-reflective information about individual objects, aggregated self-reflective information of collections of objects (such as by level, by design object type, and/or by classification combinations). According to aspects of the disclosed subject matter, the design document(s) will typically include, by way of illustration and not limitation, tables that list workspace information that compares and contrasts the designed workspace to target information. Typically, though not exclusively, the various tables that list workspace information will include “structure space” sizes or dimensions in the information (i.e., the physical size of design objects including the structure elements) as well as “usable space” sizes and dimensions in the information. Advantageously, this information can be used by the client to make decisions about the overall arrangement of the workspace, leading to important and early modifications. Further advantageously and according to various embodiments of the disclosed subject matter, the design document(s) may be generated in a format that is readily accessible to other services, such as animation or walk-through generators to create animations of the corresponding workspace, video generators to create virtual videos of the workspace, 2-D and 3-D rendering generators to create artistic renderings of the workspace, and the like.

After generating the one or more design documents from the workspace, the routine 800 terminates.

Regarding the export or generation of design documents and in accordance with aspects of the disclosed subject matter, the design document (or documents) typically, though not exclusively, includes an early schematic drawing of the workspace, often rendered in hard-edge form more closely aligned with standard engineering documents. Typically, the early schematic drawing also typically includes structure elements of the various design objects included within the workspace. As already discussed and according to aspects of the disclosed subject matter, the design document or documents include tables showing at least some of the self-reflective information about the various design objects in the workspace. These tables also typically, though not exclusively, show aggregated self-reflective information of collections of objects, often by classifications such as by level, by design object type, and/or by classification combinations. According to aspects of the disclosed subject matter, the design document(s) will typically include, by way of illustration and not limitation, tables that list workspace information that compare and contrast the designed workspace to target information. The various tables that list workspace information may but not necessarily also include “structure space” sizes or dimensions in the information (i.e., gross space) as well as “usable space” sizes and dimensions in the information. Advantageously, these tables may be used by the client to make decisions about the overall arrangement and design of the workspace. These decisions often lead to important and early modifications of the workspace, when design changes are least costly in terms of time and effort.

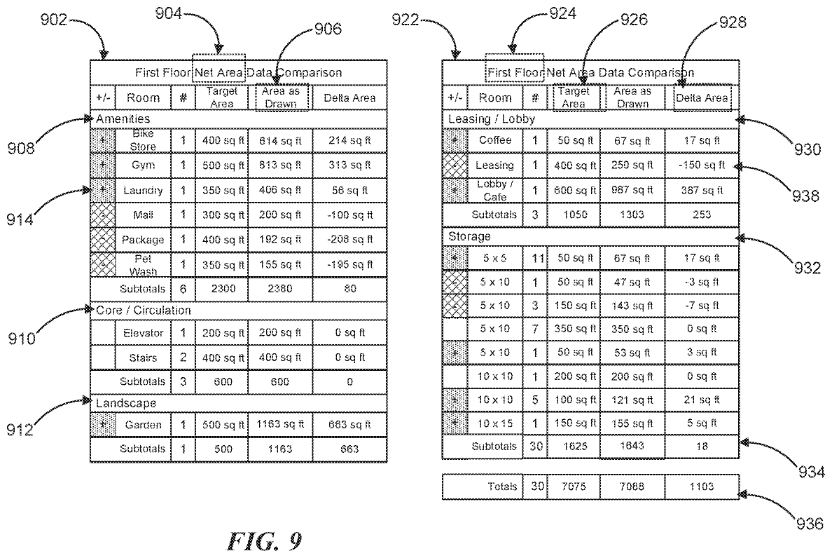

According to aspects of the disclosed subject matter, tables that are generated as part of exporting the workspace as one or more design documents are often user-configured to provide selective information for presentation to a client. The configured tables often focus on specific aspects of the workspace including, by way of illustration and not limitation, levels of a designed structure, space allocated to particular classifications, how the design space corresponds to target information, and the like. Indeed, turning to FIG. 9, this figure illustrates exemplary tables 902 and 922, the template of which may have been previously configured and generated for use in an export of a workspace, all in accordance with aspects of the disclosed subject matter.

In this illustration, reference is made to a building having at least a first level or “floor”, as indicated label 924. In this regard, only self-reflective information corresponding those design objects within the workspace that are classified as belonging to the first level are included. As indicated by label 904, only net space/usable space is shown in the tables 902 and 922. Label 926 indicates the tables 902 and 922 include target information for the design objects of level 1, the area as drawn or currently residing in the corresponding design objects as indicated by label 906, and the delta or difference between the area as drawn and the corresponding target information, as indicated by label 928.

As shown in tables 902 and 922, the pre-configured template, or newly create templates, for generating these tables also breaks out the information according to additional classifications, as shown by label the labels 908-912 and 930-932. Indeed, label 908 corresponding to a classification of “amenities”, label 910 corresponding to a classification of “core/circulation”. Further still, the self-reflective information of the included design objects are aggregated together and include subtotals, such as subtotals 934 of the “storage” classification as indicated by label 932. Similarly, the exemplary tables include “totals” 936 showing the overall net areas and deltas to targets. According to various embodiments, the templates for generating tables may be configured to readily illustrate those subtotals that are over or under targets. For example, in table 902, the listing 914 of self-reflective information for “laundry” classifications indicates a “+” in the leftmost column, showing that the “area as drawn” is larger than requested in the target information for the workspace. Conversely, in table 922, the listing 938 of self-reflective information for “leasing” classifications indicates a “−” in the leftmost column, showing that the “area as drawn” is smaller than requested in the target information for the workspace. In addition to or as an alternative to showing a symbol, colors may be used to indicate sizes that fall outside of the targeted information.

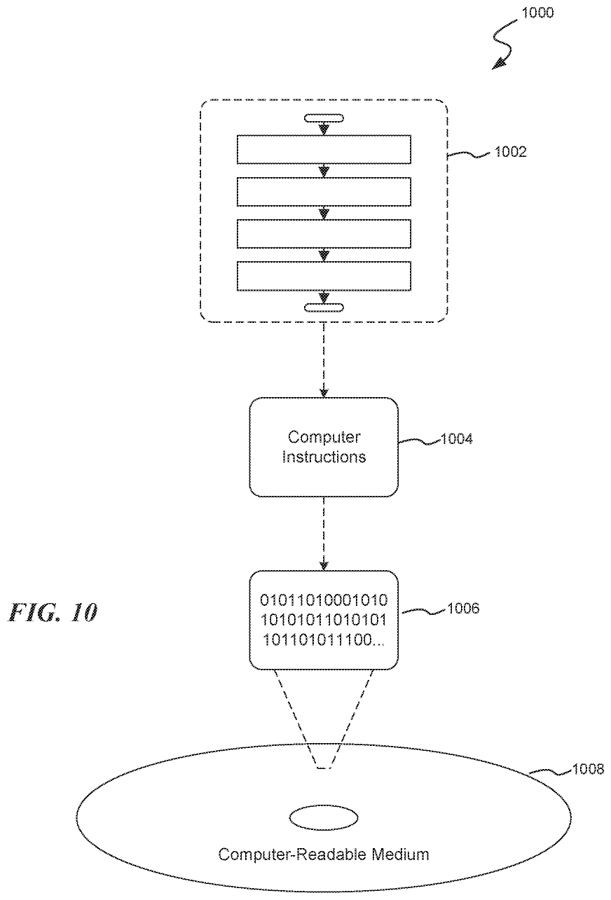

Turning now to FIG. 10, this figure is a block diagram illustrating an exemplary computer-readable medium 1000 encoded with computer-executable instructions to carry out a routine for efficient structure design in accordance with aspects of the disclosed subject matter. As will be appreciated by those skilled in the art, the implementation 1000 comprises a computer-readable medium 1008 (e.g., a CD-R, DVD-R or a platter of a hard disk drive), on which is encoded computer-readable data 1006. This computer-readable data 1006 in turn comprises a set of computer-executable instructions 1004 configured to operate according to one or more of the principles set forth herein. In one such embodiment, the computer-executable instructions 1004 may be configured to perform a method or routine, such as at least some of the exemplary methods 600 through 800, for example. In another such embodiment, the computer-executable instructions 1004 may be configured to implement a computing system, such as at least some of the exemplary computing system 1000, as described below. Many such computer-readable media may be devised, by those of ordinary skill in the art, which are configured to operate in accordance with the techniques presented herein.

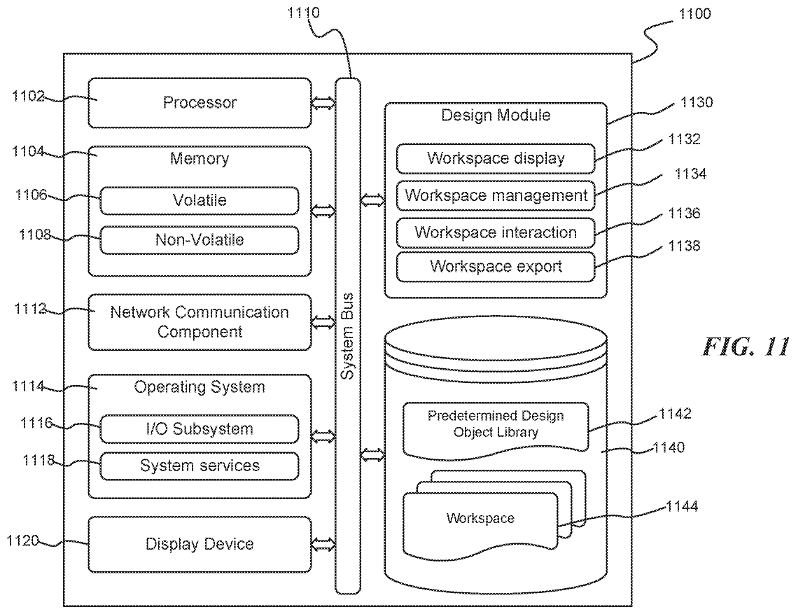

Turning now to FIG. 11, this figure is a block diagram illustrating an exemplary computing system 1100 configured to enable easy, robust and rapid design of structures according to various aspects of the disclosed subject matter.

The exemplary computing system 1100 includes one or more processors (or processing units), such as processor 1102, and a memory 1104. The processor 1102 and memory 1104, as well as other components of the computing system, are interconnected by way of a system bus 1110. The memory 1104 typically (but not exclusively) comprises both volatile memory 1106 and non-volatile memory 1108. As is known by those skilled in the art, volatile memory 1106 retains or stores information so long as the memory is supplied with power. In contrast, non-volatile memory 1108 stores (or persists) information even when a power supply is not available or applied to the memory. Generally speaking, RAM and CPU cache memory are examples of volatile memory 1106 whereas ROM, solid-state memory devices, memory storage devices, and/or memory cards are examples of non-volatile memory 1108.

As will be appreciated by those skilled in the art, the processor 1102 executes computer-executable instructions retrieved from the memory 1104 (and/or from computer-readable media, such as computer-readable media 1000 of FIG. 10) in carrying out various functions of structure design as described above. The processor 1102 may be comprised of any of number of available processors including, by way of illustration and not limitation, single-processor, multi-processor, single-core units, and multi-core units.

The illustrated computing system 1100 also includes an optional network communication component 1112 for interconnecting this computing system with other devices and/or services over a computer network. The network communication component 1112, sometimes referred to as a network interface card or NIC, communicates over a network using one or more communication protocols via a physical/tangible (e.g., wired, optical, etc.) connection, a wireless connection, or both. As will be readily appreciated by those skilled in the art, a network communication component, such as network communication component 1112, is typically comprised of hardware and/or firmware components (and may also include or comprise executable software components) that transmit and receive digital and/or analog signals over a transmission medium (i.e., the network.)

The exemplary user computing system 1100 also typically includes an operating system 1114 that provides functions and services for the computer system, including applications and apps that execute on the system. These functions and services include, by way of illustration and not limitation, an input/output (I/O) subsystem 1116 that comprises a set of hardware, software, and/or firmware components that enable or facilitate inter-communication between a user and the computing system 1100. Indeed, via the I/O subsystem 1114 a user may provide input via one or more input channels such as, by way of illustration and not limitation, touch screen/haptic input devices, buttons, pointing devices, audio input, optical input, accelerometers, and the like. Output or presentation of information may be made by way of one or more of display devices (such as display device 1120), audio speakers, haptic feedback mechanisms, and the like. As will be readily appreciated, the interaction between a user and the computer system 1100 is enabled via the I/O subsystem 1114 of the user computing device. Additionally, system services 1118 provide additional functionality including location services (e.g., GPS services), timers, interfaces with other system components such as the network communication component 1112, and the like.

The exemplary computer system 1100 also includes various executable components, typically but not exclusively implemented as software components, which configure the computer system to carry out various features and/or tasks including, but not limited to, rapid and efficient structure design. These executable components include, by way of illustration and not limitation, a design module 1130 that is configured to carry out an interactive structure design as described above. The design module may include (or be comprised of) various components including, without limitation, a workspace display module 1132, a workspace management module 1134, a workspace interaction module 1136, and a workspace export module 1138.

According to various embodiments of the disclosed subject matter, the workspace display module 1132 is configured to generate a presentation of workspace for presentation on a display, such as display device 1120, to a user. The workspace display module is configured to display a workspace, such as workspace 102 of FIG. 1A, in which a design for a desired structure is generated and/or modified by one or more users. In various embodiments, and according to aspects of the disclosed subject matter, the workspace display module 1132 is suitably configured to display representations of design objects added to a workspace in one of multiple formats include, by way of illustration and not limitation, in a hard-edge format, a rounded-edge format, as well as displaying those design objects with or without relevant target goal information. Additionally or alternatively, the workspace display module may also be suitably configured to display individual design objects within the workspace, each with a list of at least some self-reflective information, design objects contained within levels of a design structure, design objects corresponding to a set of classifications and corresponding aggregated self-reflective information, the entire designed structure, individual and aggregated self-reflective information, target/actual information illustrating target goals and how the current designed structure meets those goals, and the like.

In accordance with additional aspects of the disclosed subject matter, the workspace display module 1132 may be suitably configured to display a workspace in both a 2-D (two dimensional) or 3-D (three dimensional) manner. Indeed, while FIGS. 1A-1D illustrate a 2-D display of the corresponding workspace, in an alternative embodiment the display may be configurable such that the workspace is displayed in a 3-D manner. It should be appreciated that when displayed in a 3-D manner the display of the workspace will be “tilted”, “pivoted”, “panned over” and/or “walked through” i.e., an oblique arrangement of the z-axis relative to the display view, such that the z-axis does not point directly at the user—pointing directly to the view would result in an effective 2-D display. Further, in addition to the z-axis being titled at an oblique angle to the viewer, the various design objects in the workspace may be displayed with a measure of transparency, e.g., 70% transparent/30% opaque. Advantageously, utilizing transparency allows for the display of multiple levels of design objects that have been included within a workspace. As indicated and discussed above, FIG. 1E illustrates a 3-D presentation 130 of a workspace 132, and further illustrates the use of transparency in displaying the design objects included in the workspace.

While the workspace display module 1132 displays the design objects within the workspace, the workspace management module 1134 is suitably configured to manage the design objects that have been added to the workspace. According to various embodiments of the disclosed subject matter, the workspace management module maintains the design objects for or more workspaces as a set or as a hierarchy, such workspace 1144 in data store 1140. The workspace management module 1134 ensures that the coordinates, dimensions, and self-reflective information for the various design objects in a workspace set are kept up to date, reflecting all changes to locations and dimensions, classifications, and the like.

The workspace interaction module 1136 is suitably configured to obtain user interactions through the one of more input controls of the computer system 1100 and translate those inputs into actions for designing the desired structure. As suggested above, user inputs may correspond to adding design objects to a workspace from a predetermined design object library 1142, modifying an existing design object within the workspace, deleting design objects from the workspace, updating target information for the workspace, and the like.

The workspace export module 1138 is suitably configured to export a workspace into one or more design documents. As described above in routine 800, outputting the workspace to one or more design documents includes, by way of illustration and not limitation, rendering the design objects in hard-edge form (to include structure elements), providing self-reflective data of individual design objects, and aggregations of design objects (such as by level, by design object type, and/or by classifications).

Regarding the various components of the exemplary computer system 1100, those skilled in the art will appreciate that many of these components may be implemented as executable software modules stored in the memory of the computing device, as hardware modules and/or components (including SoCs—system on a chip), or a combination of the two. Indeed, components may be implemented according to various executable embodiments including executable software modules that carry out one or more logical elements of the processes described in this document, or as a hardware and/or firmware components that include executable logic to carry out the one or more logical elements of the processes described in this document. Examples of these executable hardware components include, by way of illustration and not limitation, ROM (read-only memory) devices, programmable logic array (PLA) devices, PROM (programmable read-only memory) devices, EPROM (erasable PROM) devices, and the like, each of which may be encoded with instructions and/or logic which, in execution, carry out the functions described herein.

While various novel aspects of the disclosed subject matter have been described, it should be appreciated that these aspects are exemplary and should not be construed as limiting. Variations and alterations to the various aspects may be made without departing from the scope of the disclosed subject matter.

What is claimed:

1. A computer-implemented method, comprising the following as implemented on a computing device comprising at least a processor, memory, a display, and one or more input devices:
presenting a view of a workspace on the display into which design objects may be placed, wherein the workspace represents physical space having defined dimensions in a coordinate system;
providing a set of predefined design objects, wherein each design object of the set of design objects:
is user-manipulable, via interaction by a user through at least one of the one or more input devices, to modify dimensions or relative location of each design object within the workspace;
comprises at least two display representation types for representation the design object in a view corresponding to the workspace, including a rounded-edge representation type and a hard-edge representation type; and
maintains self-reflective information including the relative location and the dimensions of the design object within the workspace;
receiving first user input, via at least one of the one or more input devices, to add at least two design objects to the workspace and displaying the workspace with the at least two design objects on the display;
receiving second user input, via at least one of the one or more input devices, modifying the relative location or dimension of a first design object of the at least two design objects;
in response to the second user input, modifying the relative location or dimensions of the first design object according to the modified relative location or dimensions of the first design object;
receiving third user input, via at least one of the one or more input devices, to export the workspace to a schematic document; and
in response to the third user input, outputting one or more design documents corresponding to the workspace, the one or more design documents including:
a representation of the workspace at an exported scale;
a representation of the at least two design objects, in their hard-edge representation type, at their relative locations and dimensions within the workspace, scaled according to the exported scale of the workspace; and
an information pane for each display object within the workspace, including the at least two design objects, each information pane displaying self-reflective information of a corresponding design object.

2. The computer-implemented method of claim 1, wherein the self-reflective information includes a set of classifications for the corresponding design object, and wherein representation of a corresponding design object on the display is based, at least in part, on one or more classifications of the corresponding set of classifications of the design object.

3. The computer-implemented method of claim 2, wherein the workspace is presented in at least one of a pivoted manner and a rotated manner, and wherein each design object, including the first and second design objects, are correspondingly displayed in the at least one pivoted and rotated manner, and each of the displayed design objects are displayed in a color according to the classifications of their set of classifications.

4. The computer-implemented method of claim 2, wherein the one or more classifications of the corresponding set of classifications of the design object corresponds to a color, and a representation of the corresponding design object is made in the corresponding color.

5. The computer-implemented method of claim 1, wherein the self-reflective information includes a target size, and wherein presentation of a corresponding design object on the display includes the design object's current size and a value representing a difference of the design object's current size and the target size.

6. The computer-implemented method of claim 1, wherein at least a portion of the self-reflective information is provided to a design object from the workspace.

7. The computer-implemented method of claim 1, wherein the self-reflective information includes a minimum size for a corresponding design object.

8. The computer-implemented method of claim 1, wherein each design object is presented in a partially transparent manner on the display.

9. A computer-readable medium bearing computer-executable instructions which, when executed on a computing system comprising at least a processor to execute computer-executable instructions retrieved from the medium, carry out a method comprising:
presenting a view of a workspace on the display into which design objects may be placed, wherein the workspace represents physical space having a coordinate system with defined dimensions;
providing a set of design objects, wherein each design object of the set of design objects:
is user-manipulable, via interaction by a user through at least one of the one or more input devices, to modify dimensions or relative location of each design object within to the workspace;
comprises at least two display representation types for representation in a view of the workspace, including a rounded-edge representation type and a hard-edge representation type; and
maintains self-reflective information including the relative location and the dimensions of the design object within the workspace;
receiving first user input, via at least one of the one or more input devices, to add at least two design objects to the workspace and displaying the at workspace with the at least two design objects on the display;
receiving second user input, via at least one of the one or more input devices, modifying the relative location or dimensions of a first design object of the at least two design objects;
in response to the second user input, modifying the relative location or dimensions of the first design object causing the first design object to update the self-reflective information according to the modified relative location or dimensions of the first design object;
receiving third user input, via at least one of the one or more input devices, to export one or more design documents representing the workspace; and
in response to the third user input, outputting one or more design documents corresponding to the workspace, the one or more design documents including:
a representation of the workspace at an exported scale;
a representation of the at least two design objects, in their hard-edge representation type, at their relative locations and dimensions within the workspace, scaled according to the exported scale of the workspace; and
an information pane for each display object within the workspace, including the at least two design objects, each information pane displaying self-reflective information of a corresponding design object.

10. The computer-readable medium of claim 11, wherein the self-reflective information includes a set of classifications for the corresponding design object, and wherein representation of a corresponding design object on the display is based, at least in part, on one or more classifications of the corresponding set of classifications of the design object.

11. The computer-readable medium of claim 12, wherein the workspace is presented in at least one of a pivoted manner and a rotated manner, and wherein each design object, including the first and second design objects, are correspondingly displayed in the at least one pivoted and rotated manner, and each of the displayed design objects are displayed in a color according to the classifications of their set of classifications.

12. The computer-readable medium of claim 13, wherein the one or more classifications of the corresponding set of classifications of the design object corresponds to a color, and a representation of the corresponding design object is made in the corresponding color.

13. The computer-readable medium of claim 14, wherein the self-reflective information includes a target size, and wherein presentation of a corresponding design object on the display includes the design object's current size and a value representing a difference of the design object's current size and the target size.

14. The computer-readable medium of claim 15, wherein at least a portion of the self-reflective information is provided to a design object from the workspace.

15. The computer-readable medium of claim 16, wherein the self-reflective information includes a minimum size for a corresponding design object.

16. The computer-readable medium of claim 17, wherein each design object is presented in a partially transparent manner on the display.

17. A computer system comprising a processor and a memory, wherein the processor executes computer-executable instructions to:
present a view of a workspace on the display into which design objects may be placed, wherein the workspace represents physical space having a coordinate system with defined dimensions;
provide a set of design objects, wherein each design object of the set of design objects:
is user-manipulable, via interaction by a user through at least one of the one or more input devices, to modify dimensions or relative location of each design object within to the workspace; and
maintains self-reflective information including the relative location and the dimensions of the design object within the workspace;
receive first user input, via at least one of the one or more input devices, to add at least two design objects to the workspace and displaying the at workspace with the at least two design objects on the display;
receive second user input, via at least one of the one or more input devices, modifying the relative location or dimensions of a first design object of the at least two design objects;
in response to the second user input, modify the relative location or dimensions of the first design object causing the first design object to update the self-reflective information according to the modified relative location or dimensions of the first design object;
receive third user input, via at least one of the one or more input devices, to export one or more design documents representing the workspace; and
in response to the third user input, output one or more design documents corresponding to the workspace, the one or more design documents including:
a representation of the workspace at an exported scale;
a representation of the at least two design objects, in their hard-edge representation type, at their relative locations and dimensions within the workspace, scaled according to the exported scale of the workspace; and
an information pane for each display object within the workspace, including the at least two design objects, each information pane displaying self-reflective information of a corresponding design object.

18. The computer system of claim 17, wherein each design object of the set of design objects comprises at least two display representation types for representation in a view of the workspace, including a rounded-edge representation type and a hard-edge representation type.

19. The computer system of claim 17, wherein the self-reflective information includes a set of classifications for the corresponding design object, and wherein representation of a corresponding design object on the display is based, at least in part, on one or more classifications of the corresponding set of classifications of the design object.

20. The computer system of claim 17, wherein the workspace is presented in at least one of a pivoted manner and a rotated manner, and wherein each design object, including the first and second design objects, are correspondingly displayed in the at least one pivoted and rotated manner, and each of the displayed design objects are displayed in a color according to the classifications of their set of classifications
